(19) United States
(12) Patent Application Publication
(10) Pub. No.: US 2026/0047175 A1
(43) Pub. Date: Feb. 12, 2026

(54) SEMICONDUCTOR DEVICES HAVING IMPROVED CURRENT/VOLTAGE CHARACTERISTICS AND METHODS OF FORMING THE SAME

(71) Applicant: Taiwan Semiconductor Manufacturing Company, Ltd., Hsinchu (TW)

(72) Inventors: Cheung CHENG, Hsinchu (TW); Wen-Chih CHIANG, Hsinchu (TW); Kang-Ju CHUANG, Hsinchu (TW); Tzu Jung TIEN, Hsinchu (TW)

(73) Assignee: Taiwan Semiconductor Manufacturing Company, Ltd., Hsinchu (TW)

(21) Appl. No.: 18/798,268

(22) Filed: Aug. 8, 2024

(51) Int. Cl. H01L 29/51; H01L 21/8234; H01L 27/092; H01L 29/66; H01L 29/78

(52) U.S. Cl. CPC H10D 64/683; H10D 84/0144; H10D 84/0151; H10D 84/038; H10D 84/856; H10D 30/027; H10D 30/60; H10D 64/691; H10D 64/693

(57) ABSTRACT

A semiconductor device includes a substrate, a source region, a drain region, and a channel region separating the source region from the drain region, each formed in the substrate and displaced from one another along a first direction. The semiconductor device includes a gate dielectric formed over the channel region that includes a first dielectric material, having a first dielectric permittivity, located over a center portion of the channel region and a second dielectric material, having a second permittivity that is less than the first dielectric permittivity, located over a first end and a second end of the channel region that are separated from one another by the center portion along a second direction that is perpendicular to the first direction. The semiconductor device further includes an isolation structure, having a first portion and a second portion located on opposite sides of the channel region along the second direction.

### BACKGROUND

The semiconductor industry has grown due to continuous improvements in integration density of various electronic components (e.g., transistors, diodes, resistors, inductors, capacitors, etc.). For the most part, these improvements in integration density have come from successive reductions in minimum feature size, which allow more components to be integrated into a given area. In this regard, individual transistors, interconnects, and related structures have become increasingly smaller and there is an ongoing need to develop new materials, processes, and designs of semiconductor devices and interconnects to allow further progress.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features is arbitrarily increased or reduced for clarity of discussion.

FIG. 1 is a vertical cross-sectional view of a semiconductor structure after formation of complementary metal-oxide-semiconductor (CMOS) transistors, first metal interconnect structures formed in lower-level dielectric material layers, and an isolation dielectric layer, according to various embodiments.

FIG. 2 is a vertical cross-sectional view of an intermediate structure that may be used in the formation of a semiconductor device, according to various embodiments.

FIG. 3A is a top view of a semiconductor device according to a comparative embodiment.

FIG. 3B is a vertical cross-sectional view of the semiconductor device of FIG. 3A.

FIG. 4A is a vertical cross-sectional view of a semiconductor device showing details of a channel region and isolation structure according to a comparative embodiment.

FIG. 4B is a schematic current-voltage plot for the semiconductor device of FIG. 4A.

FIG. 5A is a top view of a semiconductor device having two gate dielectric materials, according to various embodiments.

FIG. 5B is a vertical cross-sectional view of the semiconductor device of FIG. 5A, according to various embodiments.

FIG. 6A is a top view of a further semiconductor device having two gate dielectric materials, according to various embodiments.

FIG. 6B is a vertical cross-sectional view of the semiconductor device of FIG. 6A, according to various embodiments.

FIG. 7A is a top view of a semiconductor device having three gate dielectric materials, according to various embodiments.

FIG. 7B is a vertical cross-sectional view of the semiconductor device of FIG. 7A, according to various embodiments.

FIG. 8A is a top view of a semiconductor device having three gate dielectric materials, according to various embodiments.

FIG. 8B is a vertical cross-sectional view of the semiconductor device of FIG. 8A, according to various embodiments.

FIG. 9A is a top view of a semiconductor device having four gate dielectric materials, according to various embodiments.

FIG. 9B is a vertical cross-sectional view of the semiconductor device of FIG. 9A, according to various embodiments.

FIG. 10A is a top view of a semiconductor device having four gate dielectric materials, according to various embodiments.

FIG. 10B is a vertical cross-sectional view of the semiconductor device of FIG. 10A, according to various embodiments.

FIG. 11 is a flowchart illustrating operations of a method of forming a semiconductor device, according to various embodiments.

FIG. 12 is a flowchart illustrating operations of a further method of forming a semiconductor device, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows includes embodiments in which the first and second features are formed in direct contact and may also include embodiments in which additional features are formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

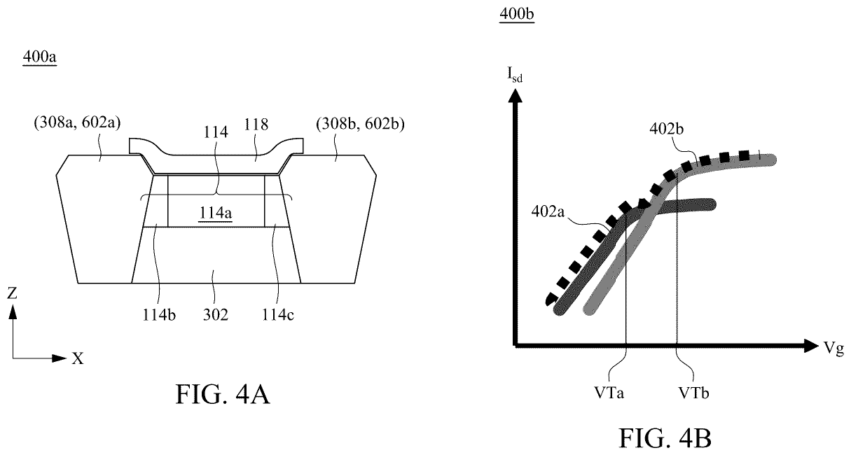

In the context of power semiconductor devices, a “double-hump source” or a “hump source” typically refers to a phenomenon where the device exhibits two distinct peaks or surges in its behavior, often in the current-voltage characteristic curve (e.g., as shown in FIG. 4B). Noise issues related to such devices can arise due to the presence of these double humps, which can complicate device operation and introduce unwanted disturbances. One significant noise concern with high-voltage devices featuring double-hump characteristics is related to switching dynamics. During switching events, such as turn-on and turn-off transitions, the device can experience abrupt changes in current or voltage levels. These rapid transitions can lead to the generation of high-frequency noise, including electromagnetic interference (EMI) and radio frequency interference (RFI). Such noise can propagate through the circuitry, affecting neighboring components and potentially causing malfunction or performance degradation. Moreover, the presence of double humps in the device's behavior may indicate non-ideal characteristics, such as oscillations or instabilities. These non-ideal behaviors can exacerbate noise-related issues, leading to unpredictable device performance and reduced reliability.

Disclosed embodiments provide advantages over existing semiconductor devices. In this regard, an embodiment of a semiconductor device includes a gate dielectric that has a composition that varies across a width of a channel region such that at least one of a work function or a dielectric permittivity has a first value over a center portion of the channel region and a second value over a first end of the channel region and a second end of the channel region. The composition variation of the gate dielectric compensates for a non-uniform electric field distribution that arises within the channel region leading to a smooth current-voltage relationship without the “hump source” that may exist in other devices that have a gate dielectric having a uniform composition.

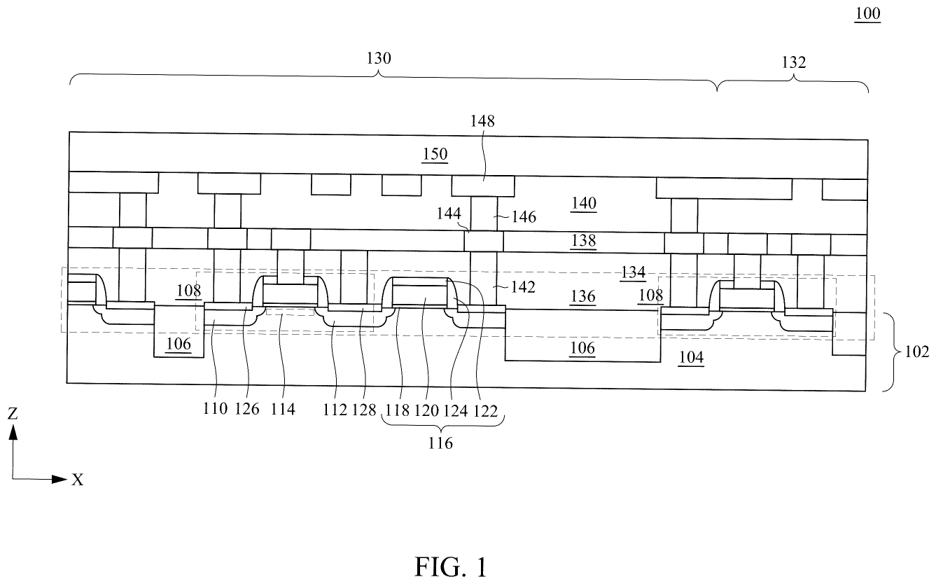

FIG. 1 vertical cross-sectional view a semiconductor structure 100, according to various embodiments. The semiconductor structure 100 includes a substrate 102, such as a silicon substrate. The substrate 102 includes a semiconductor material layer 104 on at least at an upper portion thereof. The semiconductor material layer 104 is a surface portion of a bulk semiconductor substrate or is a top semiconductor layer of a semiconductor-on-insulator (SOI) substrate. In one embodiment, the semiconductor material layer 104 includes a single crystalline semiconductor material such as single crystalline silicon.

Shallow trench isolation structures 106 (STI) including a dielectric material such as silicon oxide are formed in an upper portion of the semiconductor material layer 104. Suitably doped semiconductor wells, such as p-type wells and n-type wells, are formed within each area that is laterally enclosed by a portion of the STI 106. Field effect transistors 108 are formed over a top surface of the semiconductor material layer 104. For example, each of the field effect transistors 108 includes a source region 110, a drain region 112, a channel region 114 that includes a surface portion of the substrate 102 extending between the source region 110 and the drain region 112, and a gate structure 116. The channel region 114 includes a single crystalline semiconductor material in some embodiments.

Each gate structure 116 includes a gate dielectric layer 118, a gate electrode 120, a gate cap dielectric 122, and a dielectric gate spacer 124. A source-side metal-semiconductor alloy region 126 is formed on each source region 110, and a drain-side metal-semiconductor alloy region 128 is formed on each drain region 112. In some embodiments, the devices formed on the top surface of the semiconductor material layer 104 include complementary metal-oxide-semiconductor (CMOS) transistors and optionally additional semiconductor devices (such as resistors, diodes, capacitors, etc.), and are collectively referred to as CMOS circuitry 134.

The semiconductor structure 100 of FIG. 1 includes a memory array region 130 in which an array of memory cells may be subsequently formed. The first exemplary structure further includes a peripheral region 132 in which metal wiring for the array of memory devices is provided. Generally, the field effect transistors 108 in the CMOS circuitry 134 are electrically connected to an electrode of a respective memory cell by a respective set of metal interconnect structures.

Devices (such as field effect transistors 108) in the peripheral region 132 provide functions that operate the array of memory cells to be subsequently formed. Specifically, devices in the peripheral region are configured to control the programming operation, the erase operation, and the sensing (read) operation of the array of memory cells. For example, the devices in the peripheral region include sensing circuitry and/or programming circuitry in some embodiments.

One or more of the field effect transistors 108 in the CMOS circuitry 134 includes a channel region 114 that contains a portion of the semiconductor material layer 104 in the substrate 102. If the semiconductor material layer 104 includes a single crystalline semiconductor material such as single crystalline silicon, the channel region 114 of each of the field effect transistors 108 in the CMOS circuitry 134 includes a single crystalline semiconductor channel such as a single crystalline silicon channel. In one embodiment, a plurality of field effect transistors 108 in the CMOS circuitry 134 includes a respective node that is subsequently electrically connected to a node of a respective memory cell to be subsequently formed. For example, a plurality of field effect transistors 108 in the CMOS circuitry 134 includes a respective source region 110 or a respective drain region 112 that is subsequently electrically connected to a node of a respective memory cell to be subsequently formed.

In one embodiment, the CMOS circuitry 134 includes a programming control circuit configured to control gate voltages of a set of field effect transistors 108 that are used for programming a respective memory cell (e.g., a ferroelectric memory cell) and to control gate voltages of transistors (e.g., thin-film transistors) to be subsequently formed. In this embodiment, the programming control circuit is configured to provide a first programming pulse that programs a respective ferroelectric dielectric material layer in a selected ferroelectric memory cell into a first polarization state in which electrical polarization in the ferroelectric dielectric material layer points toward a first electrode of the selected ferroelectric memory cell, and to provide a second programming pulse that programs the ferroelectric dielectric material layer in the selected ferroelectric memory cell into a second polarization state in which the electrical polarization in the ferroelectric dielectric material layer points toward a second electrode of the selected ferroelectric memory cell.

According to an embodiment, the field effect transistors 108 are subsequently electrically connected to drain electrodes and gate electrodes of access transistors including semiconducting metal oxide plates to be formed above the field effect transistors 108. In one embodiment, a subset of the field effect transistors 108 are subsequently electrically connected to at least one of the drain electrodes and the gate electrodes. For example, the field effect transistors 108 include first word line drivers configured to apply a first gate voltage to first word lines through a first subset of lower-level metal interconnect structures to be subsequently formed, and second word line drivers configured to apply a second gate voltage to second word lines through a second subset of the lower-level metal interconnect structures. Further, the field effect transistors 108 include bit line drivers configured to apply a bit line bias voltage to bit lines to be subsequently formed, and sense amplifiers configured to detect electrical current that flows through the bit lines during a read operation.

Various metal interconnect structures formed within dielectric material layers are subsequently formed over the substrate 102 and the semiconductor devices thereupon (such as field effect transistors 108). In an illustrative example, the dielectric material layers include, for example, a first dielectric material layer 136 that is a layer that surrounds the contact structure connected to the source and drains (sometimes referred to as a contact-level dielectric material layer), a first interconnect-level dielectric material layer 138, and a second interconnect-level dielectric material layer 140. The metal interconnect structures include device contact via structures 142 formed in the first dielectric material layer 136 that contact a respective component of the CMOS circuitry 134, first metal line structures 144 formed in the first interconnect-level dielectric material layer 138, first metal via structures 146 formed in a lower portion of the second interconnect-level dielectric material layer 140, and second metal line structures 148 formed in an upper portion of the second interconnect-level dielectric material layer 140.

Each of the dielectric material layers (136, 138, 140) includes a dielectric material such as undoped silicate glass, a doped silicate glass, organosilicate glass, amorphous fluorinated carbon, porous variants thereof, or combinations thereof. Each of the metal interconnect structures (142, 144, 146, 148) includes at least one conductive material, which is a combination of a metallic liner (such as a metallic nitride or a metallic carbide) and a metallic fill material in some embodiments. Each metallic liner includes at least one of TiN, TaN, WN, TiC, TaC, and WC, and each metallic fill material portion includes at least one of W, Cu, Al, Co, Ru, Mo, Ta, Ti, TiN, alloys thereof, and/or combinations thereof in some embodiments.

Other suitable metallic liner and metallic fill materials within the contemplated scope of disclosure may also be used. In one embodiment, the first metal via structures 146 and the second metal line structures 148 are formed as integrated line and via structures by a dual damascene process. The dielectric material layers (136, 138, 140) are herein referred to as lower-level dielectric material layers. The metal interconnect structures (142, 144, 146, 148) formed within in the lower-level dielectric material layers are herein referred to as lower-level metal interconnect structures.

While the disclosure is described using an embodiment in which an array of memory cells are formed over the second line-and-via-level dielectric material layer 140, embodiments are expressly contemplated herein in which the array of memory cells are formed at a different metal interconnect level.

An array of thin-film transistors and an array of ferroelectric memory cells (or other types of semiconductor devices) are subsequently formed over the dielectric material layers (136, 138, 140) that have formed therein the metal interconnect structures (142, 144, 146, 148). The set of all dielectric material layers that are formed prior to formation of an array of thin-film transistors, an array of ferroelectric memory cells, or other semiconductor devices, is collectively referred to as lower-level dielectric material layers (136, 138, 140). The set of all metal interconnect structures that is formed within the lower-level dielectric material layers (136, 138, 140) is herein referred to as first metal interconnect structures (142, 144, 146, 148). Generally, first metal interconnect structures (142, 144, 146, 148) formed within at least one lower-level dielectric material layer (136, 138, 140) are formed over the semiconductor material layer 104 that is located in the substrate 102.

According to an embodiment, thin-film transistors or other semiconductor devices are subsequently formed in a metal interconnect level that overlies that metal interconnect levels that contain the lower-level dielectric material layers (136, 138, 140) and the first metal interconnect structures (142, 144, 146, 148). In one embodiment, a planar dielectric material layer having a uniform thickness is formed over the lower-level dielectric material layers (136, 138, 140). The planar dielectric material layer is herein referred to as an insulating matrix layer 150. The insulating matrix layer 150 includes a dielectric material such as undoped silicate glass, a doped silicate glass, organosilicate glass, or a porous dielectric material, and is deposited by chemical vapor deposition in some embodiments. The thickness of the insulating matrix layer 150 is in a range from 20 nm (i.e., 200 angstrom) to 300 nm (i.e., 3000 angstrom), although lesser and greater thicknesses may also be used.

In some embodiments, interconnect-level dielectric layers (such as the lower-level dielectric material layer (136, 138, 140)) containing therein the metal interconnect structures (such as the first metal interconnect structures (142, 144, 146, 148)) are formed over the semiconductor devices. The insulating matrix layer 150 is formed over the interconnect-level dielectric layers. In addition to other active devices that are subsequently formed, passive devices are also formed in back-end-of-line (BEOL) processes. For example, various capacitors, inductors, resistors, and integrated passive devices may be utilized with other BEOL devices.

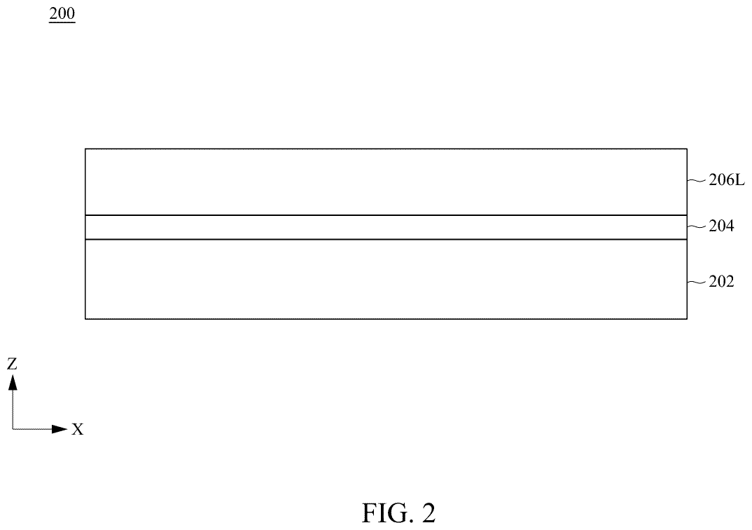

FIG. 2 is a vertical cross-sectional view of an intermediate structure 200 that may be used in the formation of a semiconductor device, according to various embodiments. The intermediate structure 200 includes a substrate 202 which is formed in a BEOL process. As such, the substrate 202 is a dielectric layer (e.g., an inter-layer dielectric or insulating matrix layer 150 from FIG. 1).

The substrate 202 includes, for example, undoped silicate glass, a doped silicate glass (e.g., deposited by decomposition of tetraethylorthosilicate (TEOS)), organosilicate glass, silicon oxynitride, or silicon carbide nitride. Other dielectric materials are within the contemplated scope of disclosure. The dielectric material of the substrate 202 is deposited by a conformal deposition process (such as a chemical vapor deposition process) or a self-planarizing deposition process (such as spin coating). The thickness of the substrate 202 is in a range from approximately 15 nm to approximately 60 nm in some embodiments, and from approximately 20 nm to approximately 40 nm in other embodiments, although smaller and larger thicknesses may also be used.

The structure 200 of FIG. 2 further includes an etch-stop layer 204 and a first inter-layer dielectric layer 206. The etch-stop layer 204 includes an etch-stop material; such as silicon nitride, silicon carbide, silicon nitride carbide; or a dielectric metal oxide; such as aluminum oxide, titanium oxide, tantalum oxide, etc. The etch-stop layer 204 is deposited by a conformal or non-conformal deposition process. In one embodiment, the etch-stop layer 204 is deposited by chemical vapor deposition (CVD), atomic layer deposition (ALD), or physical vapor deposition (PVD). A thickness of the etch-stop layer 204 is in a range from approximately 2 nm to approximately 20 nm in some embodiments, and from approximately 3 nm to approximately 12 nm in other embodiments, although smaller and larger thicknesses may also be used.

The first inter-layer dielectric layer 206 includes, but is not limited to, silicon dioxide, silicon nitride, silicon oxynitride, hafnium oxide, hafnium silicon oxide, hafnium tantalum oxide, hafnium titanium oxide, hafnium zirconium oxide, zirconium oxide, titanium oxide, aluminum oxide, hafnium dioxide-alumina, or various other insulating structures, such as a multi-layer stack structure including alternating insulating layers. The first inter-layer dielectric layer 206 is deposited by any suitable technique, such as CVD, ALD, PVD, plasma enhanced chemical vapor deposition (PECVD), etc.

In this example, the first inter-layer dielectric layer 206 is formed as a planar blanket (i.e., un-patterned) layer having a planar top surface and a planar bottom surface. Excess portions of the first inter-layer dielectric layer 206 are removed from above the top surface of the intermediate structure 200 by a planarization process, for example, by chemical mechanical planarization (CMP). A thickness of the first inter-layer dielectric layer 206 is in a range from approximately 5 nm to approximately 50 nm in some embodiments, and from approximately 20 nm to approximately 40 nm in other embodiments, although other embodiments includes smaller and larger thicknesses.

Additional semiconductor devices, such as thin film transistors, may then be formed in or over the first inter-layer dielectric layer 206. Thin-film transistors made of oxide semiconductors are an attractive option for BEOL integration since thin-film transistors are processed at low temperatures and thus, damage to previously fabricated devices is avoided. For example, the fabrication conditions and techniques may not damage previously fabricated front-end-of-line (FEOL) and middle end-of-line (MEOL) devices. Circuits based on thin-film transistor devices may further include other components that are fabricated in a BEOL process, such as capacitors, inductors, resistors, and integrated passive devices.

Various oxide semiconductors may be used to form thin film transistors, such as, but not limited to, amorphous silicon, InGaZnO, InGaO, InWO, InZnO, InSnO, ZnO, GaO, InO, and alloys thereof. Other suitable semiconducting materials are within the contemplated scope of disclosure. For example, in various embodiments, the oxide semiconductor layer 602L may include a composition given by Inₓ Ga_{y} Zn_{z} MO, wherein 0<x<1; 0≤y≤1; 0≤z≤1; and M is one of Ti, Al, Ag, Ce, and Sn. Such oxide semiconductor materials may be formed by any suitable method such as ALD, CVD, PECVD, PVD, etc.

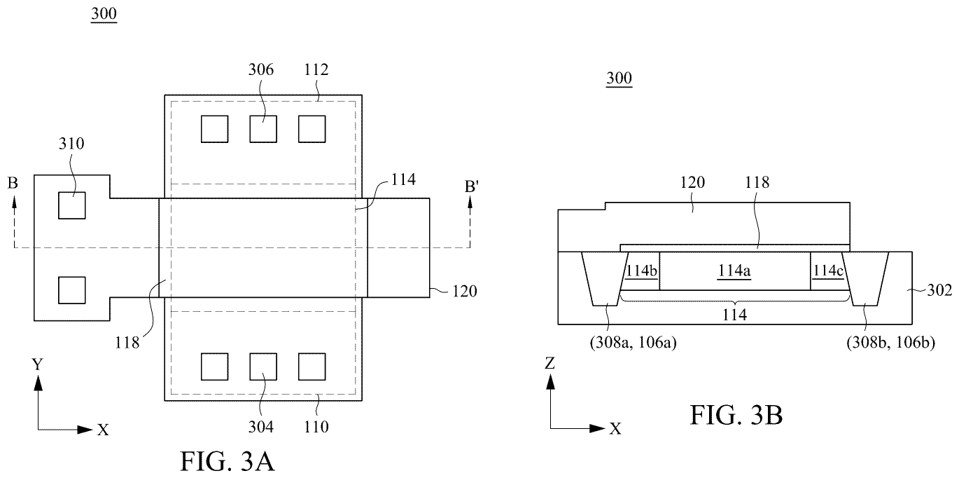

FIG. 3A is a top view of a semiconductor device 300 according to a comparative embodiment, and FIG. 3B is a vertical cross-sectional view of the semiconductor device 300 of FIG. 3A. The vertical plane that defines the cross-sectional view of the FIG. 3B is indicated by the cross-section B-B′ in FIG. 3A. The semiconductor device 300 is a transistor structure that includes a source region 110, a drain region 112, and a channel region 114 separating the source 110 region from the drain region 112. As shown in FIGS. 3A and 3B, each of the source region 110, the drain region 112, and the channel region 114, are formed in a substrate 302 (e.g., see FIG. 3B) and are displaced from one another along a first direction (i.e., the y-direction in FIG. 3A).

According to some embodiments, the substrate 302 is a semiconductor substrate, such as the substrate 102 of FIG. 1 and the semiconductor device 300 is formed in a FEOL process. Alternatively, in other embodiments, the substrate 302 is an inter-layer dielectric layer, such as the first inter-layer dielectric layer 206 of FIG. 2, and the semiconductor device 300 is formed in a BEOL process. The source region 110 is electrically connected a source electrode 304 and the drain region 112 is electrically connected to a drain electrode 306. Each of the source electrode 304 and the drain electrode 306 is electrically connected to metal interconnect structures (142, 144, 146, 148) that are formed in various dielectric material layers (136, 138, 140), as described above with reference to FIG. 1.

As shown in FIG. 3B, the semiconductor device 300 further includes an isolation structure (308a, 308b), formed in the substrate 302, including a first portion 308a and a second portion 308b located on opposite sides of the channel region 114 along a second direction (i.e., the x-direction) that is perpendicular to the first direction (i.e., the y-direction). In this example, the isolation structure (308a, 308b) is illustrated as an STI (106a, 106b) as described above with reference to FIG. 1. Various other isolation structures (not shown) may be used in other embodiments. For example, other isolation structures include local oxidation of silicon (LOCOS) structures, deep trench isolation structures (DTI), etc.

The semiconductor device 300 further includes a gate dielectric 118 formed over the channel region 114 and a gate electrode 120 formed over the gate dielectric 118. For simplicity of description, only the gate dielectric 118 and the gate electrode 120 are shown in FIGS. 3A and 3B although, in other embodiments (e.g., see FIG. 1) the semiconductor device 300 further includes a gate cap dielectric 122, a dielectric gate spacer 124, etc. The gate electrode 120 is further electrically connected to gate contacts 310 that are electrically connected to metal interconnect structures (142, 144, 146, 148) that are formed in various dielectric material layers (136, 138, 140), as described above with reference to FIG. 1.

As shown in FIG. 3B, the channel region 114 includes a center portion 114a, a first end 114b, and a second end 114c, such that the first end 114b and the second end 114c are separated from one another along the second direction (i.e., the x-direction) by the center portion 114a. For a given electrostatic potential (i.e., voltage) applied to the gate electrode 120, a non-uniform electric field distribution forms within the channel region 114. In this regard, due to the discontinuity in material properties between the ends (114b, 114c) of the channel region 114 and respective portions (308a, 308b) of the isolation structure (308a, 308b), an electric field has a greater magnitude in the respective ends (114b, 114c) of the channel region 114 relative to the center portion 114a of the channel region 114. As such, a non-uniform carrier distribution forms in the channel region 114 for a given electrostatic potential that is applied to the gate electrode 120. As such, charge carriers in the ends (114b, 114c) of the channel region 114 have a greater carrier density and a corresponding lower electrical resistance in comparison with charge carriers in the center portion 114a. Such a non-uniform carrier density gives rise to irregularities in the current-voltage profile of the device, as described in greater detail with reference to FIGS. 4A and 4B, below.

FIG. 4A is a vertical cross-sectional view of a semiconductor device 400a showing details of a channel region 114 and isolation structure (308a, 308b), according to a comparative embodiment, and FIG. 4B is a schematic current-voltage plot 400b for the semiconductor device of FIG. 4A. As shown in FIG. 4A, there are discontinuities in the material properties between the ends (114b, 114c) of the channel region 114 and respective portions (308a, 308b) of the isolation structure (308a, 308b). As such, an electric field distribution (not shown) within the channel region 114 develops a non-uniform spatial distribution.

For example, fringing fields develop near corners of the isolation structure (308a, 308b). Such fringing fields have an electric field strength that is greater in the ends (114b, 114c) of the channel region 114 than corresponding electric fields in the center portion 114a of the channel region 114, for a given voltage applied to the gate electrode 120 (see FIGS. 3A and 3B). As such, a source-drain current I_{sd} that is induced by an applied gate voltage V_{g} can be interpreted as a sum of a first electrical current 402a associated with charge carriers in the ends (114b, 114c) of the channel region 114 and a second electrical current 402b associated with charge carriers in the center portion 114a of the channel region 114. As shown in FIG. 4B, the first electrical current 402a is characterized by a first threshold voltage VTa that is lower than a second threshold voltage VTb that is associated with the second electrical current 402b. The presence of the two threshold voltages (VTa, VTb) causes disadvantageous device performance, especially in medium to high voltage applications, leading to a “double-hump source,” as described above and illustrated in FIG. 4B.

To eliminate the “double hump” features of the current-voltage relationship, disclosed embodiments provide semiconductor device structures (500, 600, 700, 800, 900, 1000) in which a gate dielectric 118 has a composition that varies along the second direction (i.e., the x-direction) such that at least one of a work function or a dielectric permittivity has a first value over the center portion 114a of the channel region 114 and a second value over the first end 114b of the channel region 114 and the second end 114c of the channel region 114.

When adjusting the threshold voltage of a semiconductor device, both the gate dielectric permittivity and the work function of the gate material are relevant considerations, though their relative importance can vary depending on specific device requirements and performance objectives. The permittivity of the gate dielectric directly influences the gate capacitance, which in turn affects the threshold voltage. High-permittivity materials, commonly referred to as high-k dielectrics, allow for increased capacitance without increasing physical thickness, thereby reducing the threshold voltage. This aspect is particularly significant in modern semiconductor fabrication, where high-k materials are replacing traditional silicon dioxide gate dielectrics.

Conversely, the gate dielectric's work function determines the energy barrier for carrier injection into the semiconductor channel. Adjusting the work function directly impacts the threshold voltage by influencing the ease with which carriers are attracted into the channel. As such, increasing the work function generally increases the threshold voltage. Device designs may be optimized by balancing both permittivity and work function adjustments to achieve the desired threshold voltage while considering factors such as leakage current, reliability, and manufacturing feasibility. Ultimately, the choice between emphasizing permittivity or work function depends on the specific operating parameters and performance goals of the semiconductor device.

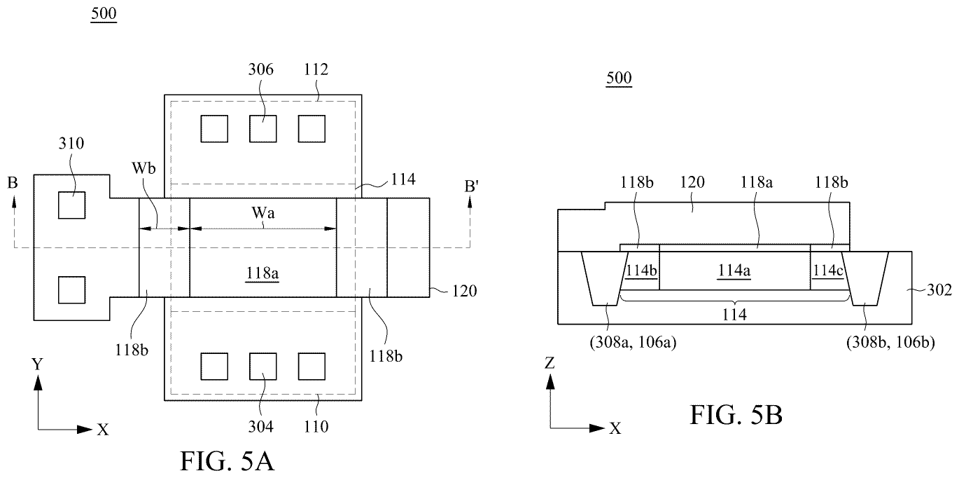

FIG. 5A is a top view of a semiconductor device 500 having two gate dielectric materials (118a, 118b), and FIG. 5B is a vertical cross-sectional view of the semiconductor device of FIG. 5A, according to various embodiments. The vertical plane that defines the cross-sectional view of the FIG. 5B is indicated by the cross-section B-B′ in FIG. 5A. As shown in FIGS. 5A and 5B, the semiconductor device 500 includes a substrate 302, a source region 110, a drain region 112, and a channel region 114 separating the source region 110 from the drain region 112, each formed in the substrate 302 and displaced from one another along a first direction (i.e., the y-direction).

The semiconductor device 500 further includes a gate dielectric (118a, 118b) formed over the channel region 114 and including a first dielectric material 118a having a first dielectric permittivity and a second dielectric material 118b having a second permittivity. To increase the first threshold voltage VTa, and/or to decrease the second threshold voltage VTb (e.g., see FIG. 4B), the second permittivity is chosen to be less than the first dielectric permittivity. In this regard, as described above, the threshold voltage generally decreases with increasing dielectric permittivity and increases with decreasing dielectric permittivity, as described in greater detail below.

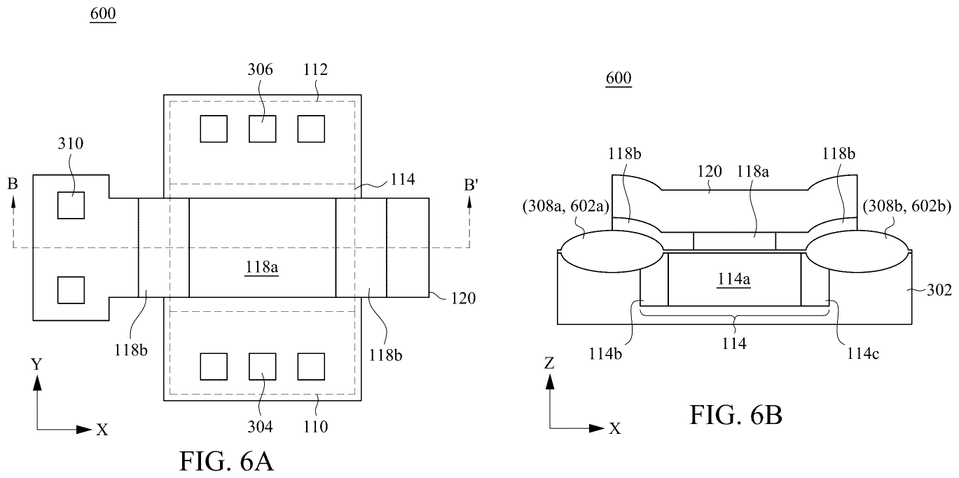

The semiconductor device 500 further includes an isolation structure (308a, 308b) formed in the substrate, including a first portion 308a and a second portion 308b located on opposite sides of the channel region 114 along a second direction (i.e., the x-direction that is perpendicular to the first direction (i.e., the y-direction). In this embodiment, the isolation structure (308a, 308b) is formed as an STI (106a, 106b). In other embodiments, the isolation structure (308a, 308b) is formed as a LOCOS structure (602a, 602b), as described in greater detail with reference to FIGS. 6A and 6B, below.

As shown in FIGS. 5A and 5B, the first dielectric material 118a is located over a center portion 114a of the channel region 114 and the second dielectric material 118b is located over a first end 114b of the channel region 114 and over a second end 114c of the channel region 114. As shown in FIG. 5B, the first end 114b and the second end 114c are separated from one another along the second direction (i.e., the x-direction) by the center portion 114a of the channel region 114. As shown in FIG. 5A, the first dielectric material 118a has a first width Wa and the second dielectric material 118b has a second width Wb. A ratio Wa/Wb may be chosen based on a spatial distribution of fringing fields in the center portion 114a of the channel region 114 and in the end portions (114a, 114b). For example, in certain embodiments, the first width Wa is between about 70% and 90% of a total width Wa+Wb. In other embodiments, Wa is between about 75% and 85% of Wa+Wb. Similarly, the second width Wb is between about 10% and 30% of the total width Wa+Wb in some embodiments and between about 15% and 25% of Wa+Wb.

By appropriate choice of the first dielectric material 118a and the second dielectric material 118b, the first threshold voltage VTa and the second threshold voltage VTb may be adjusted to coincide or to nearly coincide, thus eliminating or reducing the “double-hump” features shown in FIG. 4B. In this regard, the threshold voltage of a metal-oxide-semiconductor field-effect transistor (MOSFET) depends on the dielectric permittivity K and the thickness tₒₓ of the gate dielectric according to the following equation:

$${V}_{th} = {V}_{FB} + 2 {ϕ}_{B} + \frac{\sqrt{2 q \text{?} {N}_{A} ( 2 {ϕ}_{B} ) \text{?}}}{K \text{?}} \qquad Eq . ( 1 )$$

$$\text{?} \text{indicates text missing or illegible when filed}$$

where:
Vₜₕ: Threshold voltage T of the MOSFET
V_{FD}: Flat-band voltage
ϕ_{B}: Bulk potential (or Fermi potential)
q: Elementary charge (approximately 1.602×10⁻¹⁹ C)
K_{ε}: Relative permittivity of the semiconductor
ε₀: Permittivity of free space (approximately 8.854×10⁻¹² F/m)
N_{A}: Doping concentration in the semiconductor
tₒₓ: Thickness of the gate dielectric layer
K: Relative permittivity (dielectric constant) of the gate dielectric

Thus, from Eq. (1), increasing the dielectric permittivity K of the gate dielectric layer gives rise to a decrease in the threshold voltage Vₜₕ having a dependence that is inversely proportional to K in the third term of Eq. (1). Similarly, from Eq. (1), increasing a thickness tox of the gate dielectric layer gives rise to an increase in the threshold voltage Vₜₕ having a dependence that increases as the square root of the thickness tₒₓ of the gate dielectric layer in the third term of Eq. (1). For a given material choice of the first gate dielectric layer 118a and the second gate dielectric layer 118b, Eqs. (1) may be used to design an improved device to reduce a difference in the threshold voltages by altering the relative values of thickness tₒₓ and dielectric permittivity K.

Equation (1) can be used to make precise predictions when all of the variables listed are known. Experimental results for several embodiments indicate that threshold voltage differences (e.g., VTa−Vtb) of 10% or greater may be reduced by differences in permittivity (Ka−Kb) that are 20% or greater. Similarly, in various embodiments, threshold voltage differences (e.g., VTa−Vtb) of 10% or greater may be reduced by relative differences in thicknesses of the first dielectric layer 118a and the second dielectric layer 118b that are 6.5% or greater.

As described above, to adjust the first threshold voltage VTa and the second threshold voltage VTb to coincide with one another, the first dielectric material 118a is chosen to have a relatively high permittivity and the second dielectric material 118b is chosen to have a relatively lower permittivity. For example, the first dielectric material 118a may be chosen to be a high-k dielectric material such as one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina. Similarly, the second dielectric material 118b may be chosen to be a lower permittivity material such as silicon dioxide, silicon nitride, silicon oxynitride, silicon carbide, and silicon oxycarbide.

In addition to the permittivity of the gate dielectric (118a, 118b), various other geometric properties, such as thickness (e.g., as described above), play a role in the value of the first threshold voltage VTa and the second threshold voltage VTb. In addition, the spatial extent of the first dielectric material 118a and the second dielectric material 118b may be adjusted to control the values of the first threshold voltage VTa and the second threshold voltage VTb. For example, as shown in FIGS. 5A and 5B, the second dielectric material 118b further extends over respective edges of the first end 114b of the channel region 114 and the second end 114c of the channel region 114 such that the second dielectric material 118b is partially located over the first portion 308a and the second portion 308b of the isolation structure (308a, 308b).

Alternatively, in other embodiments, the first dielectric material 118a and the second dielectric material 118b are formed so as to not overlap with the isolation structure (308a, 308b). The choice of materials for the first dielectric material 118a, the second dielectric material 118b, and the various thicknesses and spatial extents of the gate dielectric (118a, 118b) may be optimized through the use of numerical simulations to determine device properties based on specific applications.

The above-described embodiment semiconductor device 500 is a planar device that may be formed in an FEOL or BEOL operation. Other structures, such as fin field effect transistors (FinFET) devices, gate-all-around (GAA) devices, 2D material devices, thin-film transistor devices, etc., may also include gate dielectrics having a composition that varies with position. As described above, the gate electrode 120 may include a metal, polysilicon, or other conducting material may include various dopants such as N, P, As, Sn, Bi, O, S, Se, Te, F, Cl, Br, I, B, Al, Ga, In, Ti, Ta, Si. The source and drain regions may also include various dopants such as N, P, As, Sn, Bi, O, S, Se, Te, F, Cl, Br, I, B, Al, Ga, In, Ti, Ta, Si.

FIG. 6A is a top view of a semiconductor device 600 having two gate dielectric materials (118a, 118b), and FIG. 6B is a vertical cross-sectional view of the semiconductor device of FIG. 6A, according to various embodiments. The vertical plane that defines the cross-sectional view of the FIG. 6B is indicated by the cross-section B-B′ in FIG. 6A. The semiconductor device 600 includes many of the features of semiconductor device 500 with the exception of isolation structure (308a, 308b). As shown in FIG. 6B, the isolation structure (308a, 308b) is formed as a LOCOS structure (602a, 602b).

In this regard, the LOCOS structure (602a, 602b) is formed as follows. The process begins with a silicon substrate (302, 102) onto which a layer of silicon nitride is deposited (in an FEOL process). This nitride layer serves as an oxidation mask, shielding certain areas of the silicon from oxidation. Using photolithography, a photoresist is applied and then exposed through a mask to define the oxidation pattern. The exposed nitride is then etched away to reveal the silicon areas designated for oxidation. Once the substrate is prepared, it is placed in an oxidation furnace where the exposed silicon is oxidized, forming silicon dioxide.

This oxide grows both upwards and laterally, penetrating the silicon substrate. The characteristic “bird's beak” shape that forms due to lateral oxygen diffusion under the nitride edges is a notable feature of this process. After the oxidation step, the silicon nitride mask is removed, leaving the silicon dioxide in place. This oxide acts as an insulator, defining active regions and isolating components to enhance device performance and reduce electrical interference. The LOCOS process effectively isolates the active components (e.g., source region 110, channel region 114, and drain region 112) on a chip, although the bird's beak effect can consume additional space, which may be disadvantageous for highly scaled integrated circuits. However, for certain application, the use of the LOCOS structure (602a, 602) may be advantageous in providing a spatial transition between the material properties of the channel region 114 and the isolation structure (308a, 308b) that is less abrupt. As such, the electric field distribution may have a smoother spatial dependence leading to reduced “double hump source” effects when using the LOCOS structure (602a, 602b) in certain embodiments.

After formation of the LOCOS structure (602a, 602b), the gate dielectric (118a, 118b) is deposited and patterned, and the gate 120 (e.g., metal or polysilicon) is then formed over the gate dielectric (118a, 118b). As shown in FIG. 6B, the gate dielectric (118a, 118b) and the gate 120 are no longer planar structures, as was the case with the semiconductor device 500 of FIG. 5B. As such, the electric field distribution (not shown) within the channel region 114 may have a different configuration than would occur with the semiconductor device 500 of FIGS. 5A and 5B. As such, the different geometry resulting from the use of the LOCOS structure (602a, 602b), rather than the STI structure (106a, 106b) of FIG. 5B, generally leads to different design considerations regarding choice of materials, thicknesses, widths, etc., of the gate dielectric (118a, 118b).

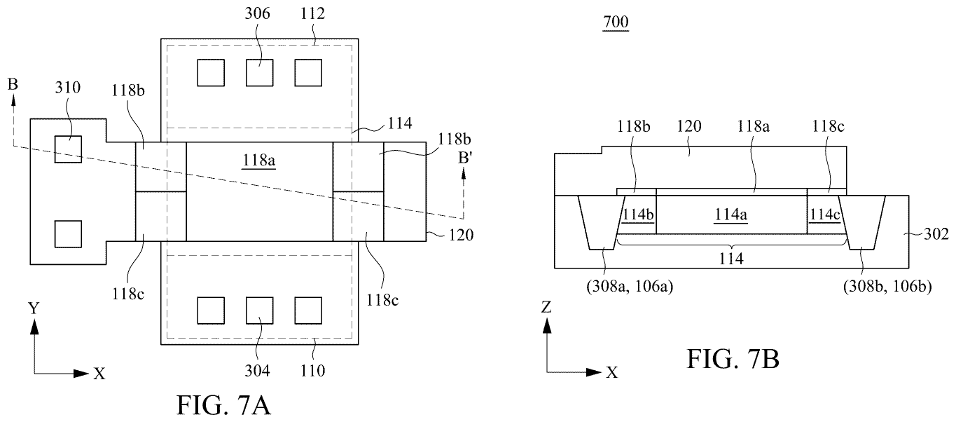

FIG. 7A is a top view of a semiconductor device 700 having three gate dielectric materials (118a, 118b, 118c), and FIG. 7B is a vertical cross-sectional view of the semiconductor device of FIG. 7A, according to various embodiments. The vertical plane that defines the cross-sectional view of the FIG. 7B is indicated by the cross-section B-B′ in FIG. 7A. As shown in FIGS. 7A and 7B, the semiconductor device 700 includes a substrate 302, a source region 110, a drain region 112, and a channel region 114 separating the source region 110 from the drain region 112, each formed in the substrate 302 and displaced from one another along a first direction (i.e., the y-direction).

The semiconductor device 500 further includes a gate dielectric (118a, 118b, 118c) formed over the channel region 114 and including a first dielectric material 118a having a first dielectric permittivity, a second dielectric material 118b having a second permittivity, and a third dielectric material 118c having a third dielectric permittivity. The first, second, and third dielectric permittivities are different from each other. The use of three dielectric permittivities allows greater flexibility to fine-tune the spatial variation of the dielectric material properties. For example, three dielectric materials have permittivities (Ka, Kb, Kc) that satisfy Ka≥Kb≥Kc. For example, the permittivity values are in the ranges 25≤Ka≤30; 15≤Kb≤20; and 5≤Kc≤10 in some embodiments.

As shown in FIG. 7A, the third dielectric material 118c is partially located over both of the first end 114b and the second end 114c of the channel region 114 adjacent to the second dielectric material 118b. In this regard, the second dielectric material 118b and the third dielectric material 118c are located adjacent to one another along an edge of the channel region 114, on each side of the channel region 114, and are displaced from one another along the first direction (i.e., the y-direction).

Various other geometric arrangements of the first dielectric material 118a, the second dielectric material 118b, and the third dielectric material 118c are also within the scope of this disclosure. For example, in other embodiments (not shown), the second dielectric material 118b and the third dielectric material 118c are formed adjacent to one another only along one edge of the channel region 114 (e.g., along an edge of the first end 114b, while only a single dielectric material (i.e., one of the first dielectric material 118a, the second dielectric material 118b, or the third dielectric material 118c) is formed along an edge of the second end 114c of the channel region 114. As with other embodiments disclosed herein, numerical simulations may be performed to determine an optimal choice of materials, thicknesses, widths, relative placement, etc., of the gate dielectric (118a, 118b, 118c).

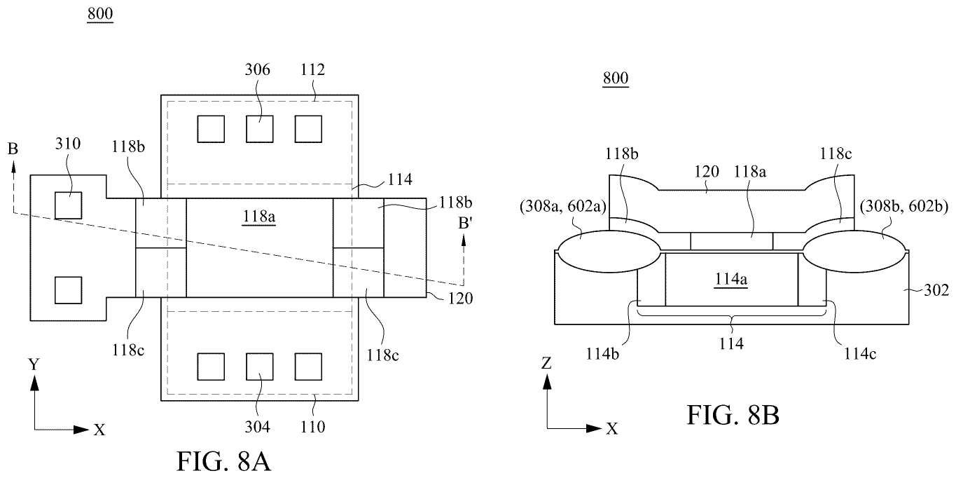

FIG. 8A is a top view of a semiconductor device 800 having three gate dielectric materials (118a, 118b, 118c), and FIG. 8B is a vertical cross-sectional view of the semiconductor device of FIG. 8A, according to various embodiments. The vertical plane that defines the cross-sectional view of the FIG. 8B is indicated by the cross-section B-B′ in FIG. 8A. The semiconductor device 800 includes many of the features of semiconductor device 700 with the exception of isolation structure (308a, 308b). As shown in FIG. 8B, the isolation structure (308a, 308b) is formed as a LOCOS structure (602a, 602b).

After formation of the LOCOS structure (602a, 602b) the gate dielectric (118a, 118b, 118c) is deposited and patterned, and the gate 120 (e.g., metal or polysilicon) is then formed over the gate dielectric (118a, 118b, 118c). As shown in FIG. 6B, the gate dielectric (118a, 118b, 118c) and the gate 120 are no longer planar structures, as was the case with the semiconductor device 700 of FIG. 7B. As such, the electric field distribution (not shown) within the channel region 114 may have a different configuration than would occur with the semiconductor device 700 of FIGS. 7A and 7B. As such, the different geometry resulting from the use of the LOCOS structure (602a, 602b) rather than the STI structure (106a, 106b) of FIG. 7B, may lead to different design considerations regarding choice of materials, thicknesses, widths, etc., of the gate dielectric (118a, 118b, 118c).

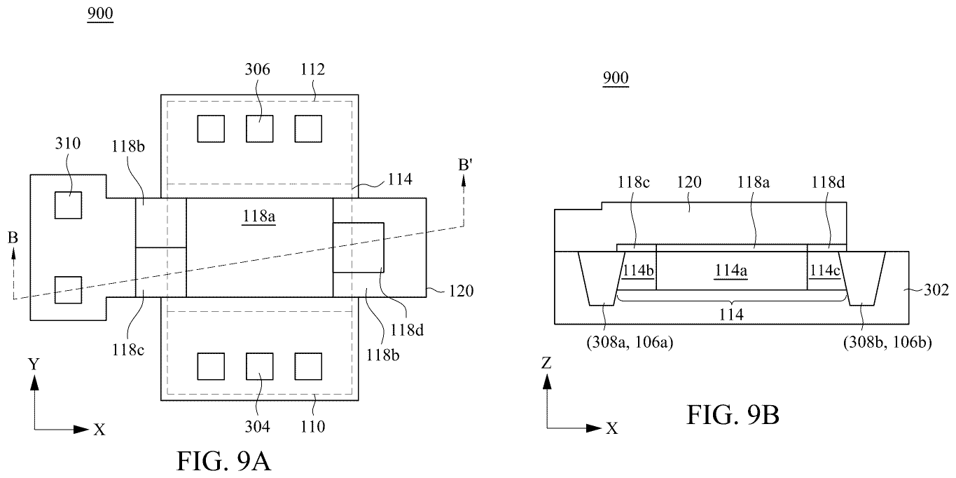

FIG. 9A is a top view of a semiconductor device 900 having four gate dielectric materials (118a, 118b, 118c, 118d), and FIG. 9B is a vertical cross-sectional view of the semiconductor device of FIG. 9A, according to various embodiments. The vertical plane that defines the cross-sectional view of FIG. 9B is indicated by the cross-section B-B′ in FIG. 9A. As shown in FIGS. 9A and 9B, the semiconductor device 900 includes a substrate 302, a source region 110, a drain region 112, and a channel region 114 separating the source region 110 from the drain region 112, each formed in the substrate 302 and displaced from one another along a first direction (i.e., the y-direction). The use of four dielectric permittivities allows greater flexibility to fine-tune the spatial variation of the dielectric material properties. In turn, the use of four dielectric permittivities may allow for tuning Vt to have a greater tunability range. In various embodiments, four dielectric materials have permittivities (Ka, Kb, Kc, Kd) that satisfy Ka≥Kb≥Kc≥Kd. For example, the permittivity values may be in the ranges 30≤Ka≤80; 25≤Kb≤30; 15≤Kc≤20; and 5≤Kd≤10.

The semiconductor device 900 further includes a gate dielectric (118a, 118b, 118c, 118d) formed over the channel region 114 and includes a first dielectric material 118a having a first dielectric permittivity, a second dielectric material 118b having a second permittivity, a third dielectric material 118c having a third dielectric permittivity, and a fourth dielectric material 118d having a fourth dielectric permittivity. The first, second, third, and fourth dielectric permittivities are different from each other. As shown in FIG. 9B, the second dielectric material 118b and the third dielectric material 118c are partially located over the first end 114b of the channel region 114, and the fourth dielectric material 118d is located over the second end 114c of the channel region 114. Further, the second dielectric material 118b and the third dielectric material 118c are located adjacent to one another along an edge of the first end 114b of the channel region 114 and are displaced from one another along the first direction (i.e., the y-direction).

Various other geometric arrangements of the first dielectric material 118a, the second dielectric material 118b, the third dielectric material 118c, and the fourth dielectric material 118d, are included within the scope of this disclosure. As with other embodiments, numerical simulations may be performed to determine an optimal choice of materials, thicknesses, widths, relative placement, etc., of the gate dielectric (118a, 118b, 118c, 118d).

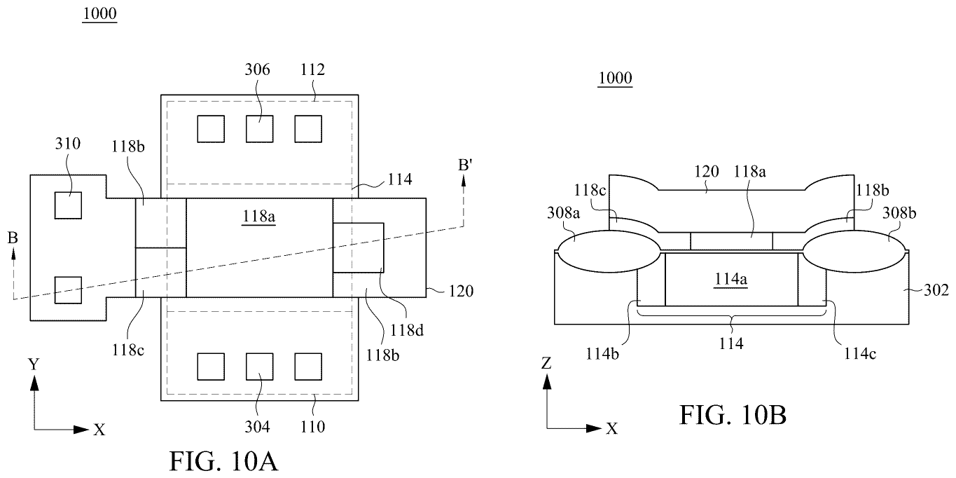

FIG. 10A is a top view of a semiconductor device 1000 having four gate dielectric materials (118a, 118b, 118c, 118d), and FIG. 10B is a vertical cross-sectional view of the semiconductor device of FIG. 10A, according to various embodiments. The vertical plane that defines the cross-sectional view of the FIG. 10B is indicated by the cross-section B-B′ in FIG. 10A. The semiconductor device 1000 includes many of the features of semiconductor device 900 with the exception of isolation structure (308a, 308b). As shown in FIG. 10B, the isolation structure (308a, 308b) is formed as a LOCOS structure (602a, 602b).

After formation of the LOCOS structure (602a, 602b) the gate dielectric (118a, 118b, 118c, 118d) is deposited and patterned, and the gate 120 (e.g., metal or polysilicon) is then formed over the gate dielectric (118a, 118b, 118c, 118d). As shown in FIG. 6B, the gate dielectric (118a, 118b, 118c, 118d) and the gate 120 are no longer planar structures, as was the case with the semiconductor device 900 of FIG. 9B. As such, the electric field distribution (not shown) within the channel region 114 may have a different configuration than would occur with the semiconductor device 900 of FIGS. 9A and 9B. As such, the different geometry resulting from the use of the LOCOS structure (602a, 602b) rather than the STI structure (106a, 106b) of FIG. 9B, may lead to different design considerations regarding choice of materials, thicknesses, widths, etc., of the gate dielectric (118a, 118b, 118c, 118d).

Each of the semiconductor device structures (500, 600, 700, 800, 900, 1000) are shown with gate dielectrics (118, 118a, 118b, 118c, 118d) such that the composition of the gate dielectric changes discontinuously from one dielectric material to another dielectric material (e.g., from first dielectric material 118a to the second dielectric material 118b, etc.). However, in other embodiments (not shown) the gate dielectric material is formed to have a composition that varies continuously along the second direction (i.e., the x-direction) such that a smooth composition gradient is formed. Further, the above-described embodiments are described with reference to choosing gate dielectric materials to have specific values for the dielectric permittivity. The work function of the gate dielectric is also a relevant consideration and may be chosen to optimize a current-voltage characteristic of the semiconductor device (500, 600, 700, 800, 900, 1000).

As described above, a relationship between the work function of the gate dielectric and the threshold voltage of a semiconductor device is a relevant variable to understanding its operation. The threshold voltage represents the voltage level at which the transistor begins to conduct current between its source and drain terminals. The threshold voltage is influenced by various factors, among which the work function of the gate dielectric plays a role. The work function determines the energy barrier for electron injection from the gate electrode into the semiconductor channel. When the work function of the gate material matches that of the semiconductor material, the threshold voltage is typically lower, enabling easier electron injection and thus lower voltage required to turn the transistor on.

Conversely, if the work function of the gate material differs significantly from that of the semiconductor material, the threshold voltage increases. Therefore, by selecting appropriate materials with compatible work functions for the gate electrode and the semiconductor material, the threshold voltage of the semiconductor device may be precisely controlled to tailor its performance to meet specific application requirements. This relationship underscores the importance of understanding and optimizing the work function of the gate dielectric 118 in semiconductor device design and fabrication. The thickness of the gate dielectric 118 is also a relevant consideration.

The relationship between the work function of the gate dielectric and the thickness of the gate dielectric in a semiconductor device is intricate and depends on several factors. As the thickness of the gate dielectric decreases, the work function may shift due to quantum mechanical effects. When the gate dielectric is thick, the influence of the semiconductor material on the work function of the gate electrode diminishes, allowing the work function to align more closely with the intrinsic properties of the gate material. However, as the gate dielectric becomes thinner, quantum tunneling effects become more pronounced, leading to changes in the effective work function. Additionally, the choice of materials for the gate dielectric can also impact this relationship, with certain materials exhibiting stronger dependence on thickness variations. Overall, understanding and controlling the relationship between the work function of the gate dielectric and its thickness is relevant for optimizing the performance of semiconductor devices, particularly in the realm of field-effect transistors where precise control over the threshold voltage is desirable.

In scenarios where the gate dielectric is sufficiently thick to mitigate quantum tunneling effects, the work function may remain relatively stable with increasing thickness. This stability arises from reduced influence from quantum mechanical phenomena as the thickness of the dielectric layer ensures a stronger insulating barrier between the gate electrode and the semiconductor channel. Consequently, the work function tends to align more closely with the intrinsic properties of the gate material. However, this behavior can vary depending on specific material compositions and processing techniques. Overall, in the absence of quantum tunneling effects, the work function of the gate dielectric tends to remain consistent as the thickness increases.

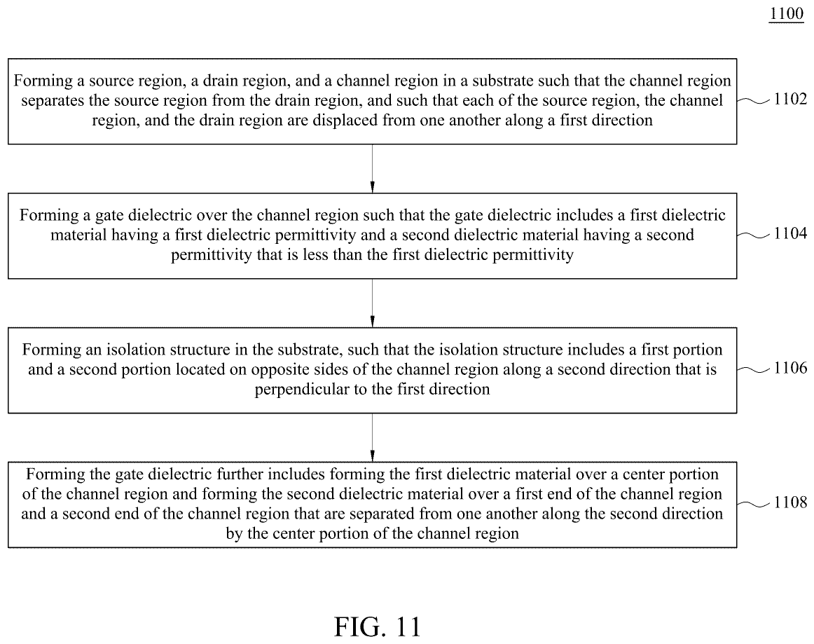

FIG. 11 is a flowchart illustrating operations of a method 1100 of forming a semiconductor device (500, 600, 700, 800, 900, 1000), according to various embodiments. In operation 1102, the method 1100 includes forming a source region 110, a drain region 112, and a channel region 114 in a substrate (102, 202, 302) such that the channel region 114 separates the source region 110 from the drain region 112, and such that each of the source region 110, the channel region 114, and the drain region 112 are displaced from one another along a first direction (i.e., the y-direction). In operation 1104, the method 1100 includes forming a gate dielectric (118a, 118b) over the channel region 114 such that the gate dielectric (118a, 118b) includes a first dielectric material 118a having a first dielectric permittivity and a second dielectric material 118b having a second permittivity that is less than the first dielectric permittivity.

In operation 1106, the method 1100 includes forming an isolation structure (308a, 308b) in the substrate (102, 202, 302), such that the isolation structure (308a, 308b) includes a first portion 308a and a second portion 308b located on opposite ends (114b, 114c) of the channel region 114 along a second direction (i.e., the x-direction) that is perpendicular to the first direction (i.e., the y-direction). In forming the gate dielectric (118a, 118b) according to operation 1108, the method 1100 further includes forming the first dielectric material 118a over a center portion 114a of the channel region 114 and forming the second dielectric material 118b over a first end 114b of the channel region 114 and over a second end 114c of the channel region 114, which are separated from one another along the second direction by the center portion 114a of the channel region 114.

In forming the gate dielectric (118a, 118b) according to operation 1104, the method 1100 further includes forming the second dielectric material 118b such that it extends over respective edges of the first end 114b of the channel region 114 and the second end 114c of the channel region 114, such that the second dielectric material 118b is partially located over the first portion 308a and over the second portion 308b of the isolation structure (308a, 308b) in some embodiments.

In forming the gate dielectric (118a, 118b, 118c) according to operation 1104, the method 1100 further includes forming the gate dielectric (118a, 118b) over the channel region 114 such that the gate dielectric (118a, 118b, 118c) includes a third dielectric material 118c having a third permittivity that is different from that of the first dielectric material 118a and the second dielectric material 118b in some embodiments. In forming the gate dielectric (118a, 118b, 118c) according to operation 1104, the method 1100 further includes forming the third dielectric material 118c over a portion of at least one of the first end 114b or the second end 114c of the channel region 114, such that the third dielectric material 118c is adjacent to the second dielectric material 118b in some embodiments. In forming the gate dielectric (118a, 118b, 118c) according to operation 1104, the method 1100 further includes forming the third dielectric material 118c over both of the first end 114b and the second end 114c of the channel region 114 adjacent to the second dielectric material 118b in some embodiments.

In some embodiments, in forming the gate dielectric (118a, 118b, 118c, 118d) according to operation 1104, the method 1100 further includes forming the gate dielectric (118a, 118b, 118c, 118d) over the channel region 114 such that the gate dielectric (118a, 118b, 118c, 118d) includes a fourth dielectric material 118d having a fourth permittivity that is different from that of the first dielectric material 118a, the second dielectric material 118b, and the third dielectric material 118c. In some embodiments, in forming the gate dielectric (118a, 118b, 118c, 118d) according to operation 1104, the method 1100 further includes forming the first dielectric material 118a to include one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina; and forming the second dielectric material 118b to include one or more of silicon dioxide, silicon nitride, silicon oxynitride, silicon carbide, and silicon oxycarbide.

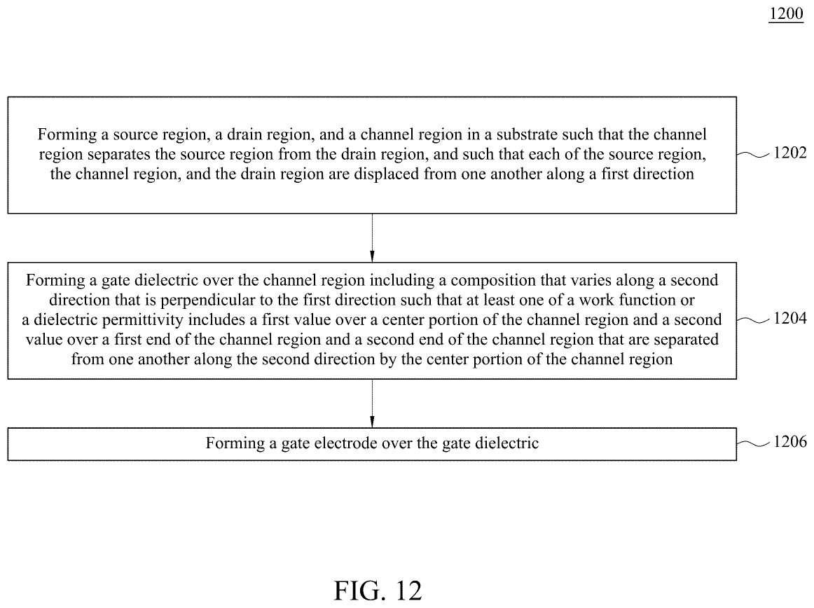

FIG. 12 is a flowchart illustrating operations of a method 1200 of forming a semiconductor device (500, 600, 700, 800, 900, 1000), according to various embodiments. In operation 1202, the method 1200 includes forming a source region 110, a drain region 112, and a channel region 114 in a substrate (102, 202, 302) such that the channel region 114 separates the source region 110 from the drain region 112, and such that each of the source region 110, the channel region 114, and the drain region 112 are displaced from one another along a first direction (i.e., the y-direction). In operation 1204, the method 1200 includes forming a gate dielectric 118 over the channel region 114 including a composition that varies along a second direction (i.e., the x-direction) that is perpendicular to the first direction (i.e., the y-direction) such that at least one of a work function or a dielectric permittivity has a first value over a center portion 114a of the channel region 114 and a second value over a first end 114b of the channel region 114 and a second end 114c of the channel region 114, which are separated from one another along the second direction by the center portion 114a of the channel region 114. In operation 1206, the method 1200 includes forming a gate electrode 120 over the gate dielectric 118.

In forming the gate dielectric 118 according to operation 1204 in some embodiments, the method 1200 further includes varying the composition of the gate dielectric 118 to include a gradient that varies smoothly along the second direction. In forming the gate dielectric (118a, 118b) according to operation 1204, in other embodiments, the method 1200 includes forming a first dielectric material 118a the center portion 114a of the channel region 114 and forming a second dielectric material 118b over the first end 114b of the channel region 114 and the second end 114c of the channel region 114, such that the composition of the gate dielectric 118 changes discontinuously from the first dielectric material 118a to the second dielectric material 118b.

In forming the gate dielectric (118a, 118b) according to operation 1204 in some embodiments, the method 1200 further includes forming the first dielectric material 118a to have a first dielectric permittivity and forming the second dielectric material 118b to have a second dielectric permittivity that is less than the first dielectric permittivity. Alternatively, the method 1200 may include forming the first dielectric material 118a to have a first work function and forming the second dielectric material 118b to have a second work function that is greater than the first work function. According to various embodiments, the method 1200 further includes forming an isolation structure (308a, 308b) in the substrate (102, 202, 302), such that the isolation structure (308a, 308b) includes a first portion 308a and a second portion 308b located on opposite sides of the channel region 114 along the second direction. In forming the gate dielectric (118a, 118b) according to operation 1204, the method 1200 further includes forming the second dielectric material 118b such that it extends over respective edges of the first end 114b of the channel region 114 and the second end 114c of the channel region 114 such that the second dielectric material 118b is partially located over the first portion 308a and the second portion 308b of the isolation structure (308a, 308b).

Referring to all drawings and according to various embodiments of the present disclosure, a semiconductor device (500, 600, 700, 800, 900, 1000) is provided. According to some embodiments, the semiconductor device (500, 600, 700, 800, 900, 1000), includes a substrate (102, 202, 302), a source region 110, a drain region 112, and a channel region 114 separating the source region 110 from the drain region 112, each formed in the substrate (102, 202, 302) and displaced from one another along a first direction. The semiconductor device (500, 600, 700, 800, 900, 1000) includes a gate dielectric (118a, 118b) formed over the channel region 114 including a first dielectric material 118a having a first dielectric permittivity and a second dielectric material 118b having a second permittivity that is less than the first dielectric permittivity. and an isolation structure (308a, 308b), formed in the substrate (102, 202, 302), The isolation structure (308a, 308b) includes a first portion 308a and a second portion 308b located on opposite sides of the channel region 114 along a second direction that is perpendicular to the first direction.

According to various embodiments, the first dielectric material 118a is located over a center portion 114a of the channel region 114 and the second dielectric material 118b is located over a first end 114b of the channel region 114 and over a second end 114c of the channel region 114 that are separated from one another along the second direction by the center portion 114a of the channel region 114. According to other embodiments, the second dielectric material 118b further extends over respective edges of the first end 114b of the channel region 114 and the second end 114c of the channel region 114 such that the second dielectric material 118b is partially located over the first portion 308a and the second portion 308b of the isolation structure (308a, 308b). According to still further embodiments, the gate dielectric (118a, 118b, 118c) further includes a third dielectric material 118c including a third permittivity that is different from that of the first dielectric material 118a and the second dielectric material 118b.

According to various embodiments, the third dielectric material 118c is located over a portion of at least one of the first end 114b or the second end 114c of the channel region 114 adjacent to the second dielectric material 118b. According to various embodiments, the third dielectric material 118c is partially located over both of the first end 114b and the second end 114c of the channel region 114 adjacent to the second dielectric material 118b. According to other embodiments, the gate dielectric 118 further includes a fourth dielectric material 118d having a fourth permittivity that is different from that of the first dielectric material 118a, the second dielectric material 118b, and the third dielectric material 118c. In various embodiments, the first dielectric material 118a includes one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina; and the second dielectric material 118b includes one or more of silicon dioxide, silicon nitride, silicon oxynitride, silicon carbide, and silicon oxycarbide.

Disclosed embodiments provide advantages over existing semiconductor devices. In this regard, a semiconductor device (500, 600, 700, 800, 900, 1000) includes a gate dielectric (118, 118a, 118b, 118c, 118d) that has a composition that varies across a width of a channel region 114 such that at least one of a work function or a dielectric permittivity has a first value over a center portion 114a of the channel region 114 and a second value over the first end 114b of the channel region 114 and over the second end 114c of the channel region 114. The composition variation of the gate dielectric (118, 118a, 118b, 118c, 118d) compensates for a non-uniform electric field distribution that arises within the channel region 114 leading to a smooth current-voltage relationship without the “hump source” that may exist in other devices that have a gate dielectric 118 having a uniform composition.

An embodiment of the disclosure includes a method of forming a semiconductor device including forming a source region, a drain region, and a channel region in a substrate such that the channel region separates the source region from the drain region, and such that each of the source region, the channel region, and the drain region are displaced from one another along a first direction. The method further includes forming a gate dielectric over the channel region such that the gate dielectric includes a first dielectric material having a first dielectric permittivity and a second dielectric material having a second permittivity that is less than the first dielectric permittivity; and forming an isolation structure in the substrate, such that the isolation structure includes a first portion and a second portion located on opposite ends of the channel region along a second direction that is perpendicular to the first direction. According to the method, forming the gate dielectric further includes forming the first dielectric material over a center portion of the channel region and forming the second dielectric material over a first end of the channel region and a second end of the channel region that are separated from one another along the second direction by the center portion of the channel region.

In various embodiments, forming the gate dielectric further includes forming the second dielectric material such that it extends over respective edges of the first end of the channel region and the second end of the channel region such that the second dielectric material is partially located over the first portion and the second portion of the isolation structure. In other embodiments, forming the gate dielectric further includes forming the gate dielectric over the channel region such that the gate dielectric includes a third dielectric material having a third permittivity that is different from that of the first dielectric material and the second dielectric material. In various embodiments, forming the gate dielectric further includes forming the third dielectric material over a portion of at least one of the first end or the second end of the channel region adjacent to the second dielectric material.

In various embodiments, forming the gate dielectric further includes forming the third dielectric material over both of the first end and the second end of the channel region adjacent to the second dielectric material. In various embodiments, forming the gate dielectric further includes forming the gate dielectric over the channel region such that the gate dielectric includes a fourth dielectric material having a fourth permittivity that is different from that of the first dielectric material, the second dielectric material, and the third dielectric material. In various embodiments, forming the gate dielectric further includes forming the first dielectric material to include one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina; and forming the second dielectric material to include one or more of silicon dioxide, silicon nitride, silicon oxynitride, silicon carbide, and silicon oxycarbide.

Another embodiment of the disclosure is a method of forming a semiconductor device including forming a source region, a drain region, and a channel region in a substrate such that the channel region separates the source region from the drain region, and such that each of the source region, the channel region, and the drain region are displaced from one another along a first direction. The method further include forming a gate dielectric over the channel region including a composition that varies along a second direction that is perpendicular to the first direction such that at least one of a work function or a dielectric permittivity includes a first value over a center portion of the channel region and a second value over a first end of the channel region and a second end of the channel region that are separated from one another along the second direction by the center portion of the channel region; and forming a gate electrode over the gate dielectric.

In various embodiments, forming the gate dielectric further includes varying the composition of the gate dielectric to include a gradient that varies smoothly along the second direction. In other embodiments, forming the gate dielectric further includes forming a first dielectric material the center portion of the channel region; and forming a second dielectric material over the first end of the channel region and the second end of the channel region, such that the composition of the gate dielectric changes discontinuously from the first dielectric material to the second dielectric material. In other embodiments, forming the gate dielectric further includes forming the first dielectric material to have a first dielectric permittivity and forming the second dielectric material to have a second dielectric permittivity that is less than the first dielectric permittivity; or forming the first dielectric material to have a first work function and forming the second dielectric material to have a second work function that is greater than the first work function.

In some embodiments, the method further includes forming an isolation structure in the substrate, such that the isolation structure includes a first portion and a second portion located on opposite sides of the channel region along the second direction. In other embodiments, forming the gate dielectric further includes forming the second dielectric material such that it extends over respective edges of the first end of the channel region and the second end of the channel region such that the second dielectric material is partially located over the first portion and the second portion of the isolation structure.

Another embodiment of the disclosure is a semiconductor device including a substrate, a source region, a drain region, and a channel region separating the source region from the drain region, each formed in the substrate and displaced from one another along a first direction, and a gate dielectric formed over the channel region and including a first dielectric material including a first dielectric permittivity and a second dielectric material including a second permittivity that is less than the first dielectric permittivity. The semiconductor device further includes an isolation structure, formed in the substrate, including a first portion and a second portion located on opposite sides of the channel region along a second direction that is perpendicular to the first direction. The first dielectric material is located over a center portion of the channel region and the second dielectric material is located over a first end of the channel region and a second end of the channel region that are separated from one another along the second direction by the center portion of the channel region.

In various embodiments, the second dielectric material further extends over respective edges of the first end of the channel region and the second end of the channel region such that the second dielectric material is partially located over the first portion and the second portion of the isolation structure. In other embodiments, the gate dielectric further includes a third dielectric material including a third permittivity that is different from that of the first dielectric material and the second dielectric material. In still other embodiments, the third dielectric material is located over a portion of at least one of the first end or the second end of the channel region adjacent to the second dielectric material. In various embodiments, the third dielectric material is partially located over both of the first end and the second end of the channel region adjacent to the second dielectric material. In various embodiments, the gate dielectric further includes a fourth dielectric material including a fourth permittivity that is different from that of the first dielectric material, the second dielectric material, and the third dielectric material.

In some embodiments, the first dielectric material includes one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina; and the second dielectric material includes one or more of silicon dioxide, silicon nitride, silicon oxynitride, silicon carbide, and silicon oxycarbide.

The foregoing outlines features of several embodiments so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A method of forming a semiconductor device, comprising:
forming a source region, a drain region, and a channel region in a substrate such that the channel region separates the source region from the drain region, and such that each of the source region, the channel region, and the drain region are displaced from one another along a first direction;
forming a gate dielectric over the channel region such that the gate dielectric comprises a first dielectric material comprising a first dielectric permittivity and a second dielectric material comprising a second permittivity that is less than the first dielectric permittivity; and
forming an isolation structure in the substrate, such that the isolation structure comprises a first portion and a second portion located on opposite ends of the channel region along a second direction that is perpendicular to the first direction,
wherein forming the gate dielectric further comprises forming the first dielectric material over a center portion of the channel region and forming the second dielectric material over a first end of the channel region and over a second end of the channel region that are separated from one another along the second direction by the center portion of the channel region.

2. The method of claim 1, wherein forming the gate dielectric further comprises forming the second dielectric material such that it extends over respective edges of the first end of the channel region and the second end of the channel region such that the second dielectric material is partially located over the first portion and the second portion of the isolation structure.

3. The method of claim 1, wherein forming the gate dielectric further comprises forming the gate dielectric over the channel region such that the gate dielectric comprises a third dielectric material comprising a third permittivity that is different from that of the first dielectric material and the second dielectric material.

4. The method of claim 3, wherein forming the gate dielectric further comprises forming the third dielectric material over a portion of at least one of the first end or the second end of the channel region adjacent to the second dielectric material.

5. The method of claim 4, wherein forming the gate dielectric further comprises forming the third dielectric material over both of the first end and the second end of the channel region adjacent to the second dielectric material.

6. The method of claim 3, wherein the gate dielectric comprises a fourth dielectric material having a fourth permittivity that is different from that of the first dielectric material, the second dielectric material, and the third dielectric material.

7. The method of claim 1, wherein:
the first dielectric material comprises one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina; and
the second dielectric material comprises one or more of silicon dioxide, silicon nitride, silicon oxynitride, silicon carbide, and silicon oxycarbide.

8. A method of forming a semiconductor device, comprising:
forming a source region, a drain region, and a channel region in a substrate such that the channel region separates the source region from the drain region, and such that each of the source region, the channel region, and the drain region are displaced from one another along a first direction;
forming a gate dielectric over the channel region comprising a composition that varies along a second direction that is perpendicular to the first direction such that at least one of a work function or a dielectric permittivity comprises a first value over a center portion of the channel region and a second value over a first end of the channel region and over a second end of the channel region that are separated from one another along the second direction by the center portion of the channel region; and
forming a gate electrode over the gate dielectric.

9. The method of claim 8, wherein forming the gate dielectric further comprises varying the composition of the gate dielectric to comprise a gradient that varies smoothly along the second direction.

10. The method of claim 8, wherein forming the gate dielectric further comprises:
forming a first dielectric material the center portion of the channel region; and
forming a second dielectric material over the first end of the channel region and the second end of the channel region, such that the composition of the gate dielectric changes discontinuously from the first dielectric material to the second dielectric material.

11. The method of claim 10, wherein:
the first dielectric material has a first dielectric permittivity and the second dielectric material has a second dielectric permittivity that is less than the first dielectric permittivity; or
the first dielectric material has a first work function and the second dielectric material has a second work function that is greater than the first work function.

12. The method of claim 10, further comprising:
forming an isolation structure in the substrate, such that the isolation structure comprises a first portion and a second portion located on opposite sides of the channel region along the second direction.

13. The method of claim 12, wherein forming the gate dielectric further comprises forming the second dielectric material such that it extends over respective edges of the first end of the channel region and the second end of the channel region such that the second dielectric material is partially located over the first portion and the second portion of the isolation structure.

14. A semiconductor device, comprising:
a substrate;
a source region, a drain region, and a channel region separating the source region from the drain region, each formed in the substrate and displaced from one another along a first direction;
a gate dielectric formed over the channel region and comprising a first dielectric material comprising a first dielectric permittivity and a second dielectric material comprising a second permittivity that is less than the first dielectric permittivity; and
an isolation structure, formed in the substrate, comprising a first portion and a second portion located on opposite sides of the channel region along a second direction that is perpendicular to the first direction,
wherein the first dielectric material is located over a center portion of the channel region and the second dielectric material is located over a first end of the channel region and a second end of the channel region that are separated from one another along the second direction by the center portion of the channel region.

15. The semiconductor device of claim 14, wherein:
the first dielectric material comprises a first width;
the second dielectric material comprises a second width;
the first width is between 70% and 90% of a total width, which is a sum of the first width and the second width.

16. The semiconductor device of claim 14, wherein the second dielectric material further extends over respective edges of the first end of the channel region and the second end of the channel region such that the second dielectric material is partially located over the first portion and the second portion of the isolation structure.

17. The semiconductor device of claim 14, wherein the gate dielectric further comprises a third dielectric material comprising a third permittivity that is different from that of the first dielectric material and the second dielectric material.

18. The semiconductor device of claim 17, wherein the third dielectric material is located over a portion of at least one of the first end or the second end of the channel region adjacent to the second dielectric material.

19. The semiconductor device of claim 17, wherein the gate dielectric further comprises a fourth dielectric material comprising a fourth permittivity that is different from that of the first dielectric material, the second dielectric material, and the third dielectric material.

20. The semiconductor device of claim 14, wherein:
the first dielectric material comprises one or more of hafnium oxide, hafnium lanthanum oxide, hafnium silicon oxide, hafnium tantalum oxide, hafnium titanium oxide, hafnium zirconium oxide, zirconium oxide, titanium oxide, aluminum oxide, and hafnium dioxide-alumina, and
the second dielectric material comprises one or more of silicon dioxide, silicon nitride, silicon oxynitride, silicon carbide, and silicon oxycarbide.
